(19) United States
(12) Patent Application Publication
(10) Pub. No.: US 2025/0244658 A1
(43) Pub. Date: Jul. 31, 2025

(54) OPTICAL PROXIMITY CORRECTION METHOD BASED ON DEEP LEARNING AND MASK MANUFACTURING METHOD COMPRISING OPTICAL PROXIMITY CORRECTION METHOD

(71) Applicant: SAMSUNG ELECTRONICS CO., LTD., SUWON-SI (KR)

(72) Inventors: MINHO KIM, SUWON-SI (KR); KYOUNGYOON PARK, SUWON-SI (KR); HANVEEN KOH, SUWON-SI (KR); USEONG KIM, SUWON-SI (KR); NAMSEOK BAE, SUWON-SI (KR); SOOYONG LEE, SUWON-SI (KR)

(21) Appl. No.: 19/036,717

(22) Filed: Jan. 24, 2025

(30) Foreign Application Priority Data
Jan. 29, 2024 (KR) 10-2024-0013380

(51) Int. Cl. G03F 1/36; G06F 30/27

(52) U.S. Cl. CPC G03F 1/36; G06F 30/27

(57) ABSTRACT

An optical proximity correction (OPC) method using a deep learning-based OPC model having improved performance and a mask manufacturing method including the OPC method are provided. The OPC method includes receiving a design layout of a target pattern, generating a first OPC model reflecting an optical phenomenon in an exposure process, with respect to the design layout, generating a second OPC model reflecting a physical characteristic of a photoresist in the exposure process, and obtaining an optical proximity corrected (OPCed) design layout by performing a simulation using an OPC model including the first OPC model and the second OPC model. Generating the second OPC model uses a first result value obtained by down-sampling an input value by using a sinc filter and a second result value obtained by down-sampling the input value by using erosion.

### CROSS-REFERENCE TO RELATED APPLICATION

This application claims priority under 35 U.S.C. § 119 to Korean Patent Application No. 10-2024-0013380, filed on Jan. 29, 2024 in the Korean Intellectual Property Office, the disclosure of which is incorporated by reference herein in its entirety.

### TECHNICAL FIELD

Embodiments of the inventive concept relate to a method of manufacturing a mask, and more particularly, to an optical proximity correction (OPC) method and a mask manufacturing method using the same.

### DISCUSSION OF RELATED ART

In a semiconductor process, photolithography using a mask may be performed to form a pattern in a semiconductor substrate, such as a wafer. A mask may be defined as a pattern transfer artifact, in which a pattern is formed of an opaque material on a transparent base material. For example, in a mask manufacturing process, a desired circuit is planned, the layout of the desired circuit is designed, and design data obtained through OPC is delivered as mask tape-out (MTO) design data. Thereafter, mask data preparation (MDP) is performed based on the MTO design data and an exposure process and the like may be performed on a mask substrate.

### SUMMARY

Embodiments of the inventive concept provide an optical proximity correction (OPC) method using an OPC model having improved performance and a mask manufacturing method including the OPC method. However, embodiments of the inventive concept are not limited thereto.

According to an embodiment of the inventive concept, there is provided an OPC method based on deep learning. The OPC method includes receiving a design layout of a target pattern, generating a first OPC model reflecting an optical phenomenon in an exposure process, with respect to the design layout, generating a second OPC model reflecting a physical characteristic of a photoresist in the exposure process, and obtaining an optical proximity corrected (OPCed) design layout by performing a simulation using an OPC model including the first OPC model and the second OPC model. Generating the second OPC model uses a first result value obtained by down-sampling an input value by using a sinc filter and a second result value obtained by down-sampling the input value by using erosion.

According to an embodiment of the inventive concept, there is provided an OPC method based on deep learning. The OPC method includes receiving a design layout of a target pattern, generating a first OPC model reflecting an optical phenomenon in an exposure process, with respect to the design layout, generating a second OPC model reflecting a physical characteristic of a photoresist in the exposure process and obtaining an OPCed design layout by performing a simulation using an OPC model including the first OPC model and the second OPC model. Generating the second OPC model includes performing a learning operation with respect to a result value by using a convolutional neural network (CNN), the result value being obtained by down-sampling an input value. At least some layers in the CNN share a parameter with each other.

According to a an embodiment of the inventive concept, there is provided a mask manufacturing method including receiving a design layout of a target pattern, generating a first OPC model of an OPC model with respect to the design layout, the first OPC model reflecting an optical phenomenon in an exposure process, generating a second OPC model of the OPC model, the second OPC model reflecting a physical characteristic of a photoresist in the exposure process, obtaining an OPCed design layout by performing a simulation using the OPC model, delivering data about the OPCed design layout as mask tape-out (MTO) design data, preparing mask data based on the MTO design data, and performing exposure on a mask substrate based on the mask data. Generating the second OPC model uses a first result value obtained by down-sampling an input value by using a sinc filter and a second result value obtained by down-sampling the input value by using erosion.

### BRIEF DESCRIPTION OF THE DRAWINGS

The above and other features of the inventive concept will become more apparent by describing in detail embodiments thereof with reference to the accompanying drawings, in which:

FIG. 1 is a schematic flowchart of an optical proximity correction (OPC) method according to an embodiment;

FIG. 2 is a detailed flowchart of an operation of generating a second OPC model in the OPC method described with reference to FIG. 1;

FIG. 3 is a block diagram illustrating the operation of generating the second OPC model in the OPC method described with reference to FIG. 1;

FIG. 4 is a diagram illustrating a sinc filter applicable to an OPC method, according to an embodiment;

FIG. 5 is a diagram illustrating erosion applicable to an OPC method, according to an embodiment;

FIG. 6 is a diagram illustrating a convolution filter of a convolutional neural network (CNN) applicable to an OPC method, according to an embodiment;

FIGS. 7A to 7D are diagrams illustrating a convolution filter in an OPC method, according to an embodiment;

FIG. 8 is a diagram illustrating a deep residual network in an OPC method, according to an embodiment;

FIGS. 9A to 9C are flowcharts illustrating OPC methods according to embodiments; and

FIG. 10 is a schematic flowchart of a method of manufacturing a mask by using an OPC method, according to an embodiment.

### DETAILED DESCRIPTION OF THE EMBODIMENTS

Embodiments of the inventive concept will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

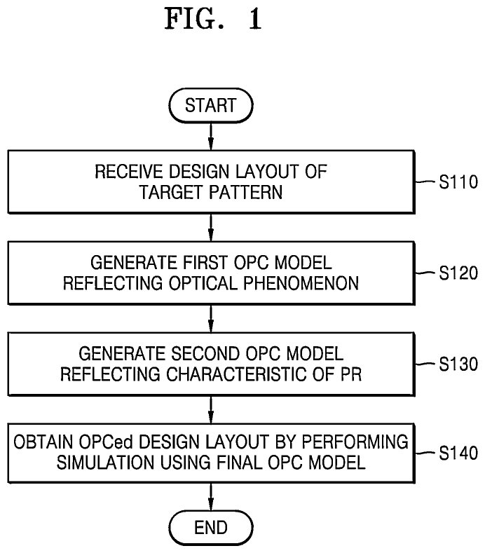

FIG. 1 is a schematic flowchart of an optical proximity correction (OPC) method according to an embodiment.

Referring to FIG. 1, the OPC method may include receiving a design layout of a target pattern to be formed on a substrate in operation S110. Here, the target pattern may refer to a pattern that is intended to be formed on a silicon (Si) substrate such as a wafer. For example, the target pattern may be formed by transferring a pattern on a mask onto a substrate through an exposure process. Because the pattern on a mask is typically projected and transferred in reduced size to a substrate, the size of the pattern on the mask may be greater than the size of the target pattern on the substrate.

The design layout may refer to the layout of a pattern on a mask in correspondence to the target pattern. Due to the nature of an exposure process, the shape of a target pattern on a wafer may be different from the shape of a pattern on a mask actually used in the exposure process. However, the shape of the initial design layout of the pattern on the mask may be substantially the same as the shape of the target pattern on the wafer. In general, a design layout may have the shape of a right-angled design layout. The shape of a right-angled design layout may refer to a shape in which edges are composed of only straight lines. For example, a design layout may have a shape of a combination of a rectangle elongated in a horizontal direction and a rectangle elongated in a vertical direction. However, the shape of a design layout is not limited to the shape of a right-angled design layout.

Thereafter, a first OPC model reflecting an optical phenomenon in the exposure process may be generated with respect to the design layout in operation S120. The first OPC model is generally referred to as an optical OPC model. The optical OPC model may be part of an OPC model used as a simulation in an OPC method.

With the miniaturization of patterns, an optical proximity effect (OPE) may occur during an exposure process because of an influence between adjacent patterns. The OPC method may refer to a method of suppressing the occurrence of an OPE by correcting the design layout of a pattern on a mask. For example, the size and the shape of a pattern formed in a wafer may be changed according to the density/arrangement of a pattern on a mask due to an OPE. The OPC method may be used to correct the change. Although various methods may be used to perform OPC, correction using an OPC model may be carried out.

The OPC method is largely classified into two kinds: a rule-based OPC method, and a simulation-based or model-based OPC method. The model-based OPC method uses the results of measuring only representative patterns without measuring all of a large amount of test patterns, and may thus reduce time and cost. In an embodiment, the OPC method may be a model-based OPC method, e.g., a correction method using an OPC model. Here, the OPC model may refer to a simulation model that outputs a result of the exposure to a wafer with respect to the design layout of a particular pattern on a mask. The OPC model may output a simulation image reflecting the mask, an optical phenomenon, and resist characteristics.

The OPC method may include not only modifying the layout of a pattern, but also a method of adding sub-lithographic features called serifs on corners of a pattern or a method of adding sub-resolution assist features (SRAFs), such as scattering bars. Here, serifs may be rectangular features on each corner of a pattern and may be used to sharpen the corners of the pattern or compensate for a distortion factor caused by the intersection of patterns. SRAF is an auxiliary feature introduced to address an OPC deviation caused by the density difference in the pattern, is formed in a smaller size than the resolution of exposure equipment, and is not transferred to a resist layer.

The OPC method includes first preparing basic data for OPC. Here, the basic data may include, for example, data about shapes of patterns of a sample, positions of the patterns, types of measurements, such as measurements of spaces or lines of the patterns, and basic measurement values. The basic data may also include information such as, for example, a thickness, a refractive index, and a dielectric constant of photoresist (PR), and a source map for a shape of an illumination system. However, the basic data is not limited to those described above.

After the basic data is prepared, the first OPC model, e.g., an optical OPC model, may be generated. The generation of the optical OPC model may include optimizing a defocus stand (DS) position and a best focus (BF) position in an exposure process. The generation of the optical OPC model may also include generating a mask image considering diffraction of light or an optical state of exposure equipment. However, the generation of the optical OPC model is not limited thereto. The generation of the optical OPC model may include various contents related to optical phenomena in the exposure process. For example, regarding the generation of an OPC model, an optical mask image, e.g., a near-field image of a mask, may be calculated first, considering the effect of mask topography. Although the near-field image of a mask may be calculated using a rigorous simulation method, such as a rigorous coupled-wave analysis (RCWA) simulation or a finite difference time domain (FDTD) simulation, an edge filter may be used for fast calculation of a mask near-field image.

After the first OPC model is generated, a second OPC model reflecting a physical characteristic of PR may be generated in operation S130. The second OPC model may be referred to as an OPC model for PR. The OPC model for PR may also be part of the OPC model used in the OPC method.

The generation of the second OPC model may include optimizing a threshold value of the PR. Here, the threshold value of the PR may refer to a threshold value at which a chemical change occurs during an exposure process. For example, the threshold value may be given as an intensity of exposure light. The generation of the second OPC model may also include selecting appropriate kernel functions from among a plurality of resist kernel functions and combining the selected kernel functions. Here, a kernel function may be a basis function used in non-parametric estimation techniques and may be used to simulate the characteristics of a resist image in the OPC model.

An integration of the optical OPC model with the OPC model for PR may be referred to as an OPC model. Accordingly, an integration of a process of generating an optical OPC model with a process of generating an OPC model for PR may be referred to as a process of generating an OPC model, e.g., an OPC modeling process. Hereinafter, an optical OPC model and the first OPC model are collectively referred to as the first OPC model, and an OPC model for PR and a second OPC model are collectively referred to as the second OPC model.

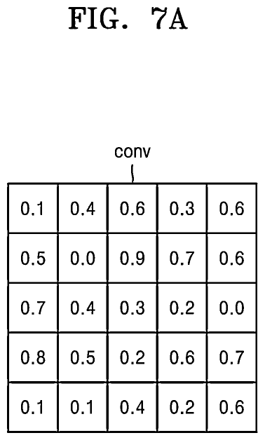

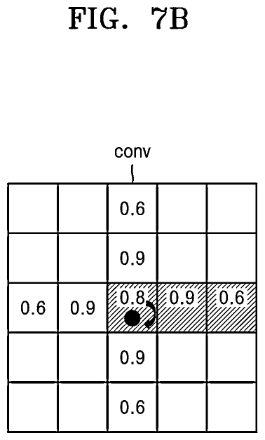

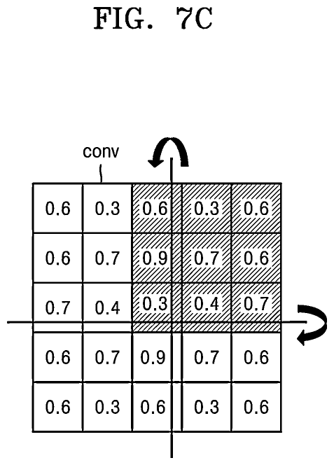

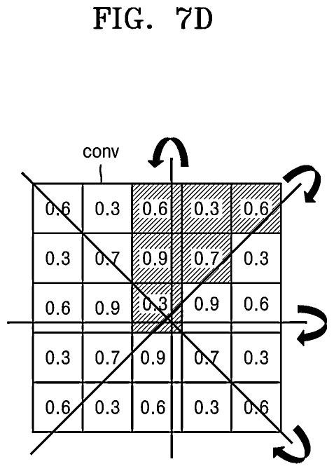

After the second OPC model is generated, an optical proximity corrected (OPCed) design layout may be obtained by performing a simulation using an OPC model in operation S140. Because the OPC model includes the first OPC model and the second OPC model, the simulation using the OPC model may include a simulation using the first OPC model and a simulation using the second OPC model. An optical image (or an aerial image) may be generated through the simulation using the first OPC model. A resist image may be generated through the simulation using the second OPC model. The optical image of the first OPC model and the physical characteristics of PR may be input to the second OPC model. The physical characteristics of PR may include characteristics based on, for example, components of PR, developer, and the shape, the slope, the thickness, and the like of a PR pattern. The physical characteristics of PR may be understood as the physical characteristics of a PR phenomenon. According to an embodiment, physical symmetry among PR characteristics may be considered in the second OPC model. This is described with reference to FIGS. 7A to 7D below.

A contour may be extracted from a simulation image (corresponding to a target pattern resulting from OPC) by the OPC model. When the contour is most similar to the target pattern, a design layout corresponding to the contour may be obtained as an OPCed design layout. Consequently, the OPC method may correspond to a process of making the contour extracted through a simulation using the OPC model as similar as possible to the shape of the target pattern. A process of simulation and comparison using the OPC model does not end at once, but rather, may be repeated tens to hundreds of times.

For example, when a design layout is initially received, the design layout may be divided into multiple segments and then input to the OPC model. A segment may be called a fragment and may refer to a straight line corresponding to an edge of a design layout or data corresponding to the straight line. Thereafter, a simulation image may be generated through a simulation using the OPC model and a contour corresponding to the target pattern may be extracted from the simulation image. Subsequently, the target pattern may be compared with the contour and an edge placement error (EPE) may be calculated. Here, the EPE may indicate the difference between an edge of the target pattern and a simulation contour. The EPE may be calculated at each of set evaluation points. Thereafter, the positions of the segments may be changed, and a contour may be extracted through a simulation using the OPC model and an EPE may be calculated. This process may be repeated until the EPE falls within a set range or until the number of repetitions reaches a set number. After termination of iteration, the final design layout may correspond to the OPCed design layout.

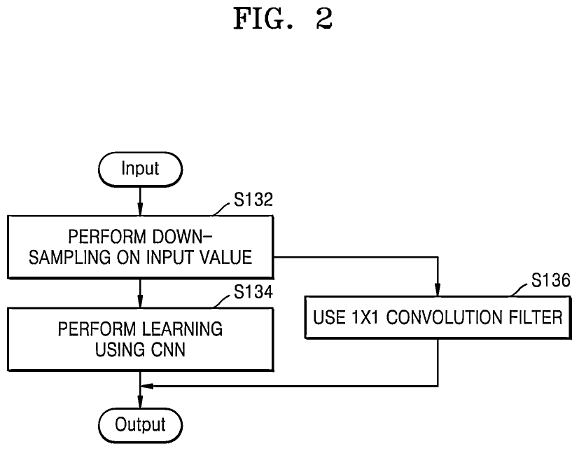

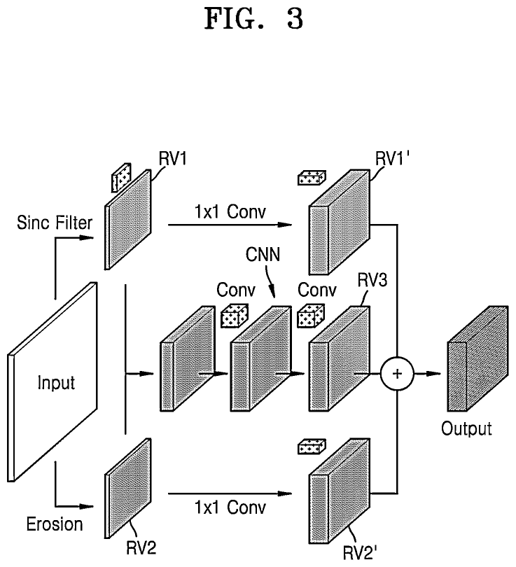

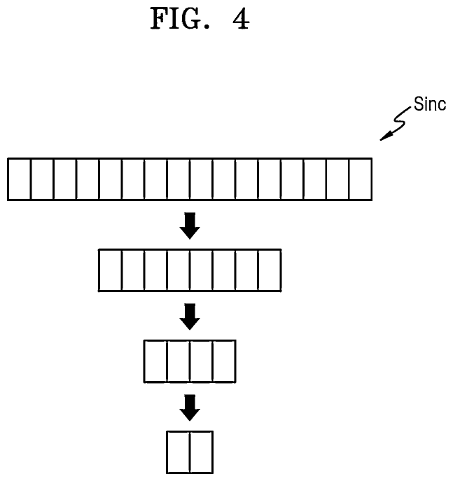

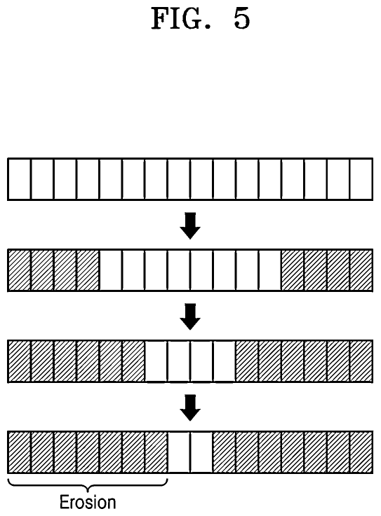

FIG. 2 is a detailed flowchart of an operation of generating the second OPC model in the OPC method described with reference to FIG. 1. FIG. 3 is a block diagram illustrating the operation of generating the second OPC model in the OPC method described with reference to FIG. 1. FIG. 4 is a diagram illustrating a sinc filter applicable to an OPC method, according to an embodiment. FIG. 5 is a diagram illustrating erosion applicable to an OPC method, according to an embodiment.

Referring to FIG. 2, operation S130 may include down-sampling an input value in operation S132, performing learning using a convolutional neural network (CNN) in operation S134, and using a 1×1 convolution filter in operation S136.

Because a sampling technique, such as stride and/or pooling, is used in a CNN generally used for image learning, signal instability may be caused in a deep neural network. Stride allows a convolution filter to be applied to input values by skipping some values rather than continuously when applied to all input values. Pooling reduces the size of an input value to be received by a subsequent layer by combining some of output values of a previous layer into one. Stride and/or pooling may cause grid dependency and aliasing of an output image in CNN.

Referring to FIGS. 2 and 3, according to an embodiment, in operation S132 in which the input value is down-sampled, the input value Input may be down-sampled (or dimensionally reduced) to a first result value RV1 by using a sinc filter and to a second result value RV2 by using erosion. By using the first result value RV1 and the second result value RV2 obtained by respectively applying a sinc filter and erosion to the input value Input, two different types of physical phenomena may be captured and grid dependency and aliasing may be reduced.

For example, the sinc filter has a characteristic of rapidly decaying at a high frequency, and may thus remove or reduce high-frequency components and enhance low-frequency components, thereby reflecting a long range effect that occurs over a wide area. The erosion may reflect a local effect by preserving a local input signal by reducing the size of the input value Input by a set erosion size before outputting the input value Input. The sinc filter is composed of a combination of trigonometric functions, so when down-sampling is performed using the sinc filter, physical characteristics of lithography may be reflected and grid dependency and aliasing may be prevented from occurring due to excessive down-sampling. For example, the sinc filter may be an anti-aliasing filter.

FIG. 4 conceptually illustrates that an input value is down-sampled by a sinc filter. Down-sampling using a sinc filter may be implemented by a convolution operation, in which the sinc filter is substituted for a convolution filter W in Equation 1.

$${O}_{i j} = {\sum }_{a b} {I}_{i + a , j + b} {W}_{a b} , \qquad [ Equation 1 ]$$

where I is an input value, O is an output value, and W is the convolution filter.

FIG. 5 conceptually illustrates that an input value is down-sampled by erosion. Down-sampling using erosion may be implemented by reducing the size of an input value by a set erosion size before outputting the input value, as described above, and may be expressed as Equation 2. For example, the erosion may be understood as cutting opposite ends of the input value by “n” in an “i” direction and cutting opposite ends of the input value by “m” in a “j” direction.

$${O}_{i j} = {I}_{n < i < N - n , m < j < M - m} , \qquad [ Equation 2 ]$$

where I is an input value, O is an output value, “n” is an erosion size in the “i” direction, N is the size of the input value in the “i” direction, “m” is an erosion size in the “j” direction, and M is the size of the input value in the “j” direction.

Referring back to FIGS. 2 and 3, after the first result value RV1 and the second result value RV2, which are obtained by down-sampling the input value Input in operation S132, are concatenated with each other, learning is performed using a CNN in operation S134. The CNN is a type of deep learning model mainly used for image processing and may automatically learn the features of images and perform various tasks using a result of the learning.

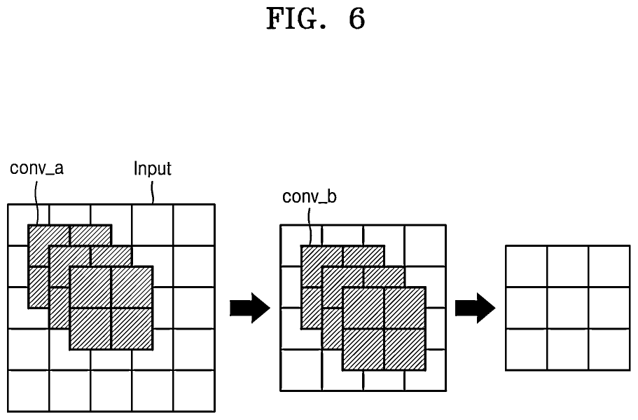

FIG. 6 is a diagram illustrating a convolution filter of a CNN applicable to an OPC method, according to an embodiment.

In the OPC method according to an embodiment, at least some of neural network layers may use the same convolution filters (or kernels). For example, according to an embodiment, at least some layers of the CNN used in the OPC method may share a parameter with each other. FIG. 6 schematically illustrates that convolution filters conv_a and conv_b are applied to the input value Input of each layer. According to an embodiment, the convolution filter conv_a used in the leftmost layer in FIG. 6 may be the same as the convolution filter conv_b used in the middle layer in FIG. 6. As described above, when at least some layers of the CNN share a parameter, many layers may be used without increasing the number of parameters, and accordingly, the second OPC model may have high convergence and predictive power. The input value Input in FIG. 6 may indicate the sum of the first result value RV1 and the second result value RV2, which are obtained by down-sampling the input value Input in FIG. 3.

FIGS. 7A to 7D are diagrams illustrating a convolution filter conv used in an OPC method, according to an embodiment. FIG. 7A illustrates a state in which a value used in the convolution filter conv is randomly determined. When the number of pieces of data is large, the convergence of an OPC model may be sufficiently secured even if randomly determined values are initially used in the convolution filter conv. However, when the number of pieces of data is small, over-fitting may occur.

According to an embodiment, the convolution filter conv used in the OPC method may be determined by reflecting physical symmetry inherent in PR. For example, the convolution filter conv may include radial symmetry or dihedral symmetry. FIG. 7B shows an example of applying radial symmetry to the convolution filter conv. FIGS. 7C and 7D show examples of applying dihedral symmetry to the convolution filter conv. As described above, when the physical symmetry of PR is reflected in the form of the convolution filter conv, the number of parameters may be reduced and the convergence and predictive power of the OPC model may be secured.

Referring back to FIGS. 2 and 3, operation S130, in which the second OPC model is generated, may include applying a 1×1 convolution filter to the input value Input, which has undergone the down-sampling, in operation S136. The input value Input may be down-sampled to the first result value RV1 by a sinc filter and to the second result value RV2 by erosion. Thereafter, the 1×1 convolution filter may be applied to each of the first result value RV1 and the second result value RV2 so that the number of channels of each of the first result value RV1 and the second result value RV2 may be adjusted. For example, the number of channels of each of the first result value RV1 and the second result value RV2 may be adjusted such that each of the number of channels of a 1×1 convolution filtered first result value RV1′ and the number of channels of a 1×1 convolution filtered second result value RV2′ is the same as the number of channels of a third result value RV3 obtained through the CNN. A final output value Output of the second OPC model may be obtained by adding the 1×1 convolution filtered first result value RV1′, the 1×1 convolution filtered second result value RV2′, and the third result value RV3.

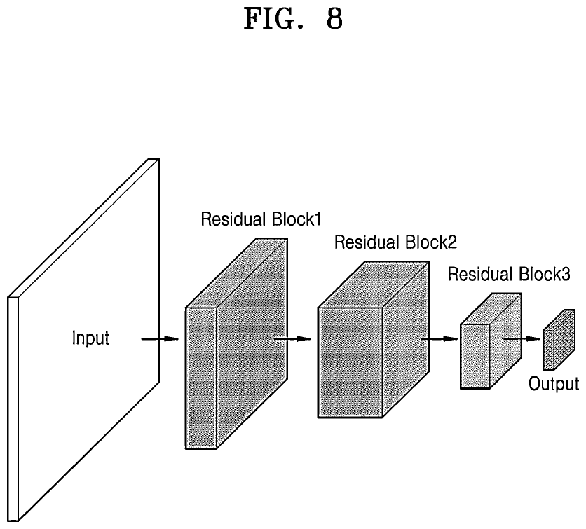

FIG. 8 is a diagram illustrating a deep residual network in an OPC method, according to an embodiment.

As described above with reference to FIGS. 2 and 3, according to an embodiment, the OPC method may include down-sampling an input value Input in operation S132, performing learning using a CNN in operation S134, and using a 1×1 convolution filter in operation S136, which may form a residual network block. FIG. 8 illustrates a deep residual network used in an OPC method, according to an embodiment, where the deep residual network is formed by stacking residual blocks in FIG. 3 in multiple layers (e.g., Residual Block1, Residual Block2, and Residual Block3).

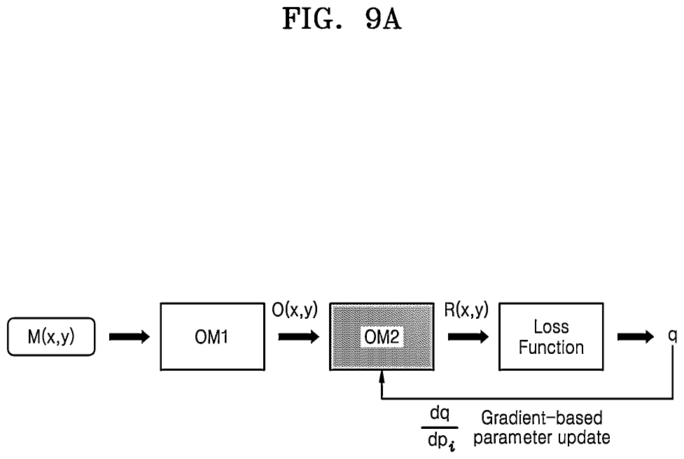

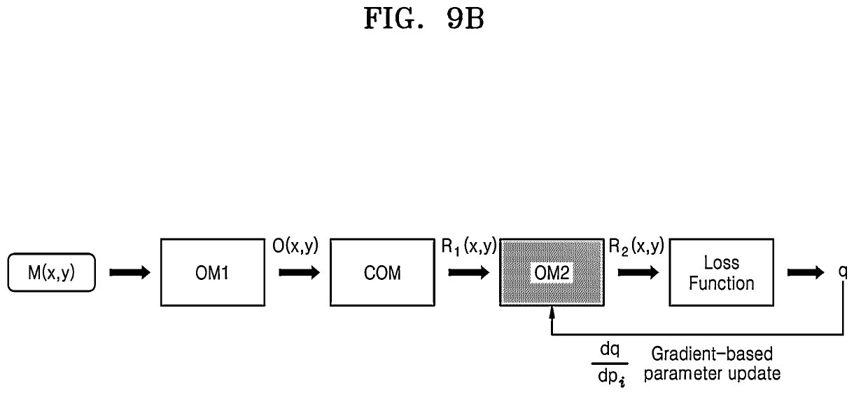

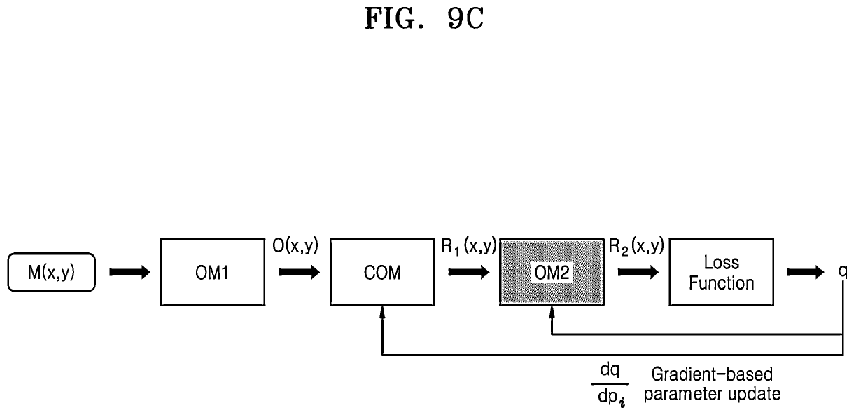

FIGS. 9A to 9C are flowcharts illustrating OPC methods according to embodiments.

According to an embodiment, the OPC method may include obtaining a resist image by using the second OPC model, calculating a scalar loss value with respect to the resist image by using a loss function, calculating a gradient with respect to a parameter of the second OPC model by using the scalar loss value, and adjusting the parameter of the second OPC model. For example, a loss may be decreased by adjusting the parameter of the second OPC model by using a backward operation.

Referring to FIG. 9A, a design layout M(x, y) of a target pattern may be received. An optical image O(x, y) may be obtained through a first OPC model OM1 that reflects an optical phenomenon in an exposure process with respect to the design layout M(x, y). Thereafter, a resist image R(x, y) may be obtained by inputting the optical image O(x, y) to a second OPC model OM2, which is described above with reference to FIGS. 2 and 3. Subsequently, a gradient dq/dpᵢ with respect to a parameter of the second OPC model OM2 and a loss value “q” may be calculated by applying a loss function to the resist image R(x, y). As a result, the parameter of the second OPC model OM2 may be adjusted (or updated). This process may be repeated so that the loss value “q” sufficiently converges.

Referring to FIG. 9B, a design layout M(x, y) of a target pattern may be received. An optical image O(x, y) may be obtained through a first OPC model OM1 that reflects an optical phenomenon in an exposure process with respect to the design layout M(x, y). Thereafter, unlike an embodiment according to FIG. 9A, a preliminary resist image R₁(x, y) may be obtained by applying a compact OPC model COM, which has been pre-trained, to the optical image O(x, y). Thereafter, a resist image R₂(x, y) may be obtained by inputting the preliminary resist image R₁(x, y) to a second OPC model OM2, which is described above with reference to FIGS. 2 and 3. Like FIG. 9A, a gradient dq/dpᵢ with respect to the parameter of the second OPC model OM2 and a loss value “q” may be calculated by applying a loss function to the resist image R₂(x, y). Through the repetition of the calculation, the parameter of the second OPC model OM2 may be adjusted (or updated).

Referring to FIG. 9C, a design layout M(x, y) of a target pattern may be received. An optical image O(x, y) may be obtained through a first OPC model OM1 that reflects an optical phenomenon in an exposure process with respect to the design layout M(x, y). Thereafter, unlike an embodiment according to FIG. 9B, a preliminary resist image R₁(x, y) may be obtained by applying a compact OPC model COM, which has not been trained, to the optical image O(x, y). Thereafter, a resist image R₂(x, y) may be obtained by inputting the preliminary resist image R₁(x, y) to a second OPC model OM2, which is described above with reference to FIGS. 2 and 3. Like FIG. 9A, a gradient dq/dpᵢ with respect to the parameter of the second OPC model OM2 and a loss value “q” may be calculated by applying a loss function to the resist image R₂(x, y). Through the repetition of the calculation, the parameter of the second OPC model OM2 may be adjusted (or updated). In an embodiment according to FIG. 9C, unlike FIGS. 9A and 9B, not only the parameter of the second OPC model OM2, but also a parameter of the compact OPC model COM may be adjusted (or updated). The compact OPC model COM of FIGS. 9B and 9C may be obtained by expressing a mask, an optical phenomenon, and a resist characteristic in a combination of simple mathematical expressions.

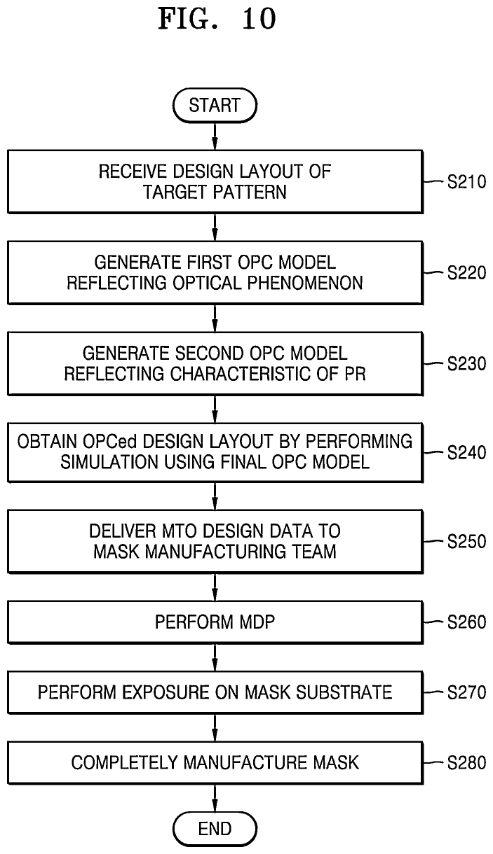

FIG. 10 is a schematic flowchart of a method of manufacturing a mask by using an OPC method, according to an embodiment.

According to an embodiment, the method of manufacturing a mask by using an OPC method (hereinafter, referred to as a “mask manufacturing method”) may include operations S210 to S240, which are sequentially performed. A design layout of a target pattern may be received in operation S210 and an OPCed design layout may be obtained in operation S240. Operations S210 to S240 may be substantially the same as operations S110 to S140 in the OPC method described with reference to FIG. 1.

Thereafter, mask tape-out (MTO) design data may be delivered to a mask manufacturing team in operation S250. In general, MTO may refer to sending data about a final design layout obtained through an OPC method to a mask manufacturing team and requesting the manufacture of a mask. Accordingly, in the mask manufacturing method of an embodiment, the MTO design data may refer to an OPCed design layout obtained through the OPC method or data about the OPCed design layout. The MTO design data may have a graphic data format used in electronic design automation (EDA) software. For example, the MTO design data may have a data format such as graphic data system II (GDS2) or open artwork system interchange standard (OASIS).

Thereafter, mask data preparation (MDP) may be performed in operation S260. For example, the MDP may include i) format conversion called fracturing; ii) augmentation of a bar code for machine reading, a standard mask pattern for inspection, or a job deck; and iii) automatic and manual verifications. Here, the job deck may refer to creation of a text file about a series of instructions including information about the arrangement of multiple mask files, a reference dose, or an exposure speed or method.

The format conversion, e.g., fracturing, may refer to a process of dividing the MTO design data into regions and converting the MTO design data into a format for an electron beam (e-beam) writer. For example, the fracturing may include data manipulation such as scaling, data sizing, rotation of data, or pattern reflection. In the conversion process through the division, data about numerous systematic errors, which may occur in a process of sending design data to an image on a wafer, may be corrected.

The correction of the data about the systematic errors may be referred to as mask process correction (MPC), which may include critical dimension (CD) adjustment and an operation of increasing pattern arrangement accuracy. Accordingly, the fracturing may contribute to an increase in quality of a mask and may be performed in advance for the MPC. Here, the systematic errors may be caused by distortion occurring during, for example, an exposure process, a mask development and etching process, a wafer imaging process, or the like.

The MDP may include MPC. As described above, the MPC is a process of correcting errors, e.g., systematic errors, occurring during an exposure process. Here, the exposure process may be a concept generally including e-beam writing, development, etching, and baking. In addition, data processing may be performed before the exposure process. The data processing may be preprocessing of mask data and include grammar check on the mask data and exposure time prediction.

After the MDP, exposure may be performed on a mask substrate based on the mask data in operation S270. Here, exposure may refer to, for example, electron (e)-beam writing. For example, the e-beam writing may be performed by a gray writing method using a multi-beam mask writer (MBMW). The e-beam writing may also be performed using a variable shape beam (VSB) writer.

After the MDP, a process of converting the mask data into pixel data may be performed before the exposure process. The pixel data may be directly used for actual exposure and include data about the shape of an object to be exposed and data about a dose allocated to the data about the shape. Here, the data about the shape may include bit-map data, into which shape data corresponding to vector data has been converted through rasterization.

After the exposure process, a series of processes may be performed to completely manufacture the mask in operation S280. For example, the series of processes may include development, etching, and cleaning. The series of processes may also include measurement, defect inspection, or defect repair. The series of processes may further include pellicle coating. The pellicle coating may refer to a process of attaching a pellicle to a mask after confirming that there are no pollutant particles or chemical stains through final cleaning and inspection so as to protect the surface of the mask from contamination during the shipment and working life of the mask.

While the inventive concept has been particularly shown and described with reference to embodiments thereof, it will be understood that various changes in form and details may be made therein without departing from the spirit and scope of the inventive concept as defined by the following claims.

What is claimed is:

1. An optical proximity correction (OPC) method based on deep learning, the OPC method comprising:
receiving a design layout of a target pattern;
generating a first OPC model reflecting an optical phenomenon in an exposure process, with respect to the design layout;
generating a second OPC model reflecting a physical characteristic of a photoresist in the exposure process; and
obtaining an optical proximity corrected (OPCed) design layout by performing a simulation using an OPC model including the first OPC model and the second OPC model,
wherein generating the second OPC model uses a first result value obtained by down-sampling an input value by using a sinc filter and a second result value obtained by down-sampling the input value by using erosion.

2. The OPC method of claim 1, wherein generating the second OPC model includes concatenating the first result value with the second result value and performing a learning operation using a convolutional neural network (CNN).

3. The OPC method of claim 2, wherein at least some of neural network layers in the CNN use a same convolution filter.

4. The OPC method of claim 2, wherein a convolution filter used in the CNN is determined by reflecting a physical symmetry of the photoresist.

5. The OPC method of claim 4, wherein the convolution filter includes radial symmetry or dihedral symmetry.

6. The OPC method of claim 2, wherein generating the second OPC model further includes applying a 1×1 convolution filter to each of the first result value and the second result value,
wherein a number of channels of each of the first result value and the second result value is adjusted to be equal to a number of channels of a third result value obtained by the CNN.

7. The OPC method of claim 6, wherein generating the second OPC model further includes obtaining a final output value by adding the first result value that the 1×1 convolution filter has been applied to, the second result value that the 1×1 convolution filter has been applied to, and the third result value.

8. The OPC method of claim 1, further comprising:
obtaining a resist image by using the second OPC model;
calculating a scalar loss value with respect to the resist image by using a loss function; and
calculating a gradient with respect to a parameter of the second OPC model by using the scalar loss value and adjusting the parameter of the second OPC model.

9. The OPC method of claim 8, wherein obtaining the resist image by using the second OPC model includes having, as the input value, an optical image calculated through the first OPC model.

10. The OPC method of claim 8, wherein obtaining the resist image by using the second OPC model includes having, as the input value, a preliminary resist image calculated by applying a compact OPC model to an optical image calculated through the first OPC model.

11. The OPC method of claim 10, further comprising:
calculating a gradient with respect to a parameter of the compact OPC model by using the scalar loss value and adjusting the parameter of the compact OPC model.

12. An optical proximity correction (OPC) method based on deep learning, the OPC method comprising:
receiving a design layout of a target pattern;
generating a first OPC model reflecting an optical phenomenon in an exposure process, with respect to the design layout;
generating a second OPC model reflecting a physical characteristic of a photoresist in the exposure process; and
obtaining an optical proximity corrected (OPCed) design layout by performing a simulation using an OPC model including the first OPC model and the second OPC model,
wherein generating the second OPC model includes performing a learning operation with respect to a result value by using a convolutional neural network (CNN), the result value being obtained by down-sampling an input value, wherein at least some layers in the CNN share a parameter with each other.

13. The OPC method of claim 12, wherein a convolution filter used in the CNN includes a radial symmetry or a dihedral symmetry.

14. The OPC method of claim 12, wherein the result value includes a first result value obtained by applying a sinc filter as an anti-aliasing filter to the input value.

15. The OPC method of claim 14, wherein the result value includes a second result value obtained by applying erosion to the input value, the erosion reducing the input value by a set erosion size.

16. The OPC method of claim 15, wherein the result value is obtained by concatenating the first result value with the second result value.

17. A mask manufacturing method, comprising:
receiving a design layout of a target pattern;
generating a first optical proximity correction (OPC) model of an OPC model with respect to the design layout, the first OPC model reflecting an optical phenomenon in an exposure process;
generating a second OPC model of the OPC model, the second OPC model reflecting a physical characteristic of a photoresist in the exposure process;
obtaining an optical proximity corrected (OPCed) design layout by performing a simulation using the OPC model;
delivering data about the OPCed design layout as mask tape-out (MTO) design data;
preparing mask data based on the MTO design data; and
performing an exposure on a mask substrate based on the mask data,
wherein generating the second OPC model uses a first result value obtained by down-sampling an input value by using a sinc filter and a second result value obtained by down-sampling the input value by using erosion.

18. The mask manufacturing method of claim 17, wherein generating the second OPC model includes concatenating the first result value with the second result value and performing a learning operation using a convolutional neural network (CNN), and
at least some of neural network layers in the CNN use a same convolution filter.

19. The mask manufacturing method of claim 18, wherein a convolution filter used in the CNN includes a radial symmetry or a dihedral symmetry.

20. The mask manufacturing method of claim 17, further comprising:
obtaining a resist image by using the second OPC model;
calculating a scalar loss value with respect to the resist image by using a loss function; and
calculating a gradient with respect to a parameter of the second OPC model by using the scalar loss value and adjusting the parameter of the second OPC model.
